(19) United States
(12) Patent Application Publication
(10) Pub. No.: US 2024/0375230 A1
(43) Pub. Date: Nov. 14, 2024

(54) FLY-CUT APPARATUS

(71) Applicant: TOKYO SEIMITSU CO., LTD., Tokyo (JP)

(72) Inventor: Kazumasa ISHIKAWA, Tokyo (JP)

(21) Appl. No.: 17/642,189

(22) PCT Filed: Apr. 14, 2021
(86) PCT No.: PCT/JP2021/015402

§ 371 Date: May 21, 2024

(30) Foreign Application Priority Data
Aug. 20, 2020 (JP) 2020-139473

(51) Int. Cl. B23Q 11/10; B23D 5/00; B23Q 17/20; B24B 41/06

(52) U.S. Cl. CPC B23Q 11/10; B23D 5/00; B23Q 17/20; B24B 41/06

(57) ABSTRACT

A fly-cut apparatus to process a work with bumps on a front surface. A fly-cut apparatus cuts an upper surface of a BG film laminated to a work including a bump region with bumps formed on a front surface and an outer peripheral region around the bump region. The fly-cut apparatus includes a fly-cut tool, a tool spindle with a lower end to which the fly-cut tool is attached, and capable of ascending and descending in a state of rotating the fly-cut tool, and a chuck which rotatably retains the work, and the fly-cut tool cuts the upper surface of the BG film from a center toward an outer perimeter.

### TECHNICAL FIELD

The present invention relates to fly-cut apparatuses which cut a protective film laminated to a work with bumps formed on a front surface.

### BACKGROUND ART

In the semiconductor manufacturing field, to thinly and flatly grind a semiconductor wafer (hereinafter referred to as “work”) such as a silicon wafer, a grinding surface of a rotating grindstone is pushed onto the work to grind the back surface of the work. To grind the back surface of the work, a film to protect the front surface is laminated to the work to protect chips and bumps formed on the front surface of the work.

When grinding the back surface of the work ends, a dicing film is laminated to the back surface of the work in a dicing-film laminating apparatus, thereby integrating the work and a dicing frame. Next, after the protective film laminated to the front surface of the work is peeled, the work is subjected to dicing into dice. A chip formed by dicing is picked up and mounted on a lead frame (for example, refer to PTL 1).

Specifically, a work 100 is processed by a procedure depicted in FIG. 9. That is, in the work 100, bumps 102 are formed on a front surface 101, and a BG film 103 is laminated so as to cover the bumps 102 (BG-film lamination process). Then, in a state in which the work 100 is absorbed and retained by a chuck table 105 so that a back surface 104 is oriented upward, the back surface 104 is ground by a grindstone 106 (work grinding process). Then, laser light is gathered to the inside of the work 100 to form a modification line 107 at a predetermined depth from the back surface 104 (laser dicing (ML) process). Then, the back surface 104 of the work 100 is absorbed by a chuck 108 of a transfer arm, and the work 100 is transferred to a DC-tape laminating apparatus (work transfer process). Then, in a state in which the work 100 is translocated and retained in a transposed chuck 109, a rolling roller 110 presses and laminates a DC tape 111 onto the back surface 104 of the work 100. After the work 100 is retained in a dicing frame 112, the BG film 103 is peeled via a peeling tape 113 (DC-tape laminating, BG-film peeling process).

### CITATION LIST

### Patent Literature

PTL 1: Japanese Unexamined Patent Application Publication No. 2009-206475

### SUMMARY OF INVENTION

### Technical Problem

However, when the work 100 is processed with the procedure depicted in FIG. 9, the BG film 103 swells more at the center of the work 100 by the bumps 102 than the outer perimeter. Thus, a leak occurs from a gap between the outer perimeter of the BG film 103 and the chuck table 105, and absorption and retainment of the work 100 tends to be insufficient. At the time of grinding, the work 100 tends to flap, thereby possibly damaging the work 100. Furthermore, since the outer peripheral side of the work 100 tends to be ground thicker than the center side, there are possibilities that: the modification line 107 is formed as being significantly shifted in a depth direction of the work 100 in the following ML process; negative pressure occurs between the chuck 108 and the work 100 in the transfer process; and a microcrack to the extent of being undetectable even by image inspection occurs in the work 100 when a peeling force greater than the adhesive force of the BG film 103 acts on the work 100 in the peeling process.

Thus, a technical problem to be solved in order to safely process the work with bumps formed on the front surface occurs, and an object of the present invention is to solve this problem.

### Solution to Problem

To achieve the above-described object, the fly-cut apparatus according to the present invention cuts an upper surface of a protective film laminated to a work including a bump region with bumps formed on a front surface and an outer peripheral region around the bump region. The fly-cut apparatus includes a fly-cut tool, a tool spindle with a lower end to which the fly-cut tool is attached, and capable of ascending and descending in a state of rotating the fly-cut tool, and a chuck which rotatably retains the work, and the fly-cut tool cuts the upper surface of the protective film from a center toward an outer perimeter.

According to this structure, with a center region being cut to be relatively thinner than an outer peripheral region of the protective film, when the upper surface side of the protective film is absorbed and retained by the chuck, the entire surface of the protective film can be absorbed and retained by the chuck. Thus, the work can be safely ground. Also in the ML process, the modification line is formed at a substantially constant depth from the back surface of the work. Thus, the occurrence of a microcrack in the work can be reduced in the transfer process and the peeling process.

### Advantageous Effects of Invention

In the present invention, since the work with bumps is formed with a substantially uniform thickness over the entire surface, the entire surface of the protective film is absorbed and retained by the chuck, and the work can be safely ground. Also, since the modification line is formed at a substantially constant depth from the back surface of the work in the ML process, the occurrence of a microcrack in the work can be reduced in the transfer process and the peeling process

### BRIEF DESCRIPTION OF DRAWINGS

FIG. 1 is a schematic view depicting an overview of a fly-cut apparatus according to one embodiment of the present invention.

FIG. 2 (a) is a perspective view of a fly-cut tool, and FIG. 2 (b) is an enlarged view of a main part of the fly-cut tool.

FIG. 3 is a plan view depicting a position of a fly-cut line and a measurement position of a thickness sensor.

FIG. 4 (a) is a plan view of the work. FIG. 4 (b) is a longitudinal sectional view of the work. FIG. 4 (c) is an enlarged view of a main part of the work.

FIG. 5 is a schematic view depicting a procedure of processing a work with bumps.

FIG. 6 is a schematic view depicting a procedure of cutting a BG film.

FIG. 7 is a plan view schematically depicting a positional relation between adjacent fly-cut lines.

FIG. 8 is a side view schematically depicting a positional relation between the fly-cut tool and the chuck.

FIG. 9 is a schematic view depicting a conventional procedure of process a work with bumps.

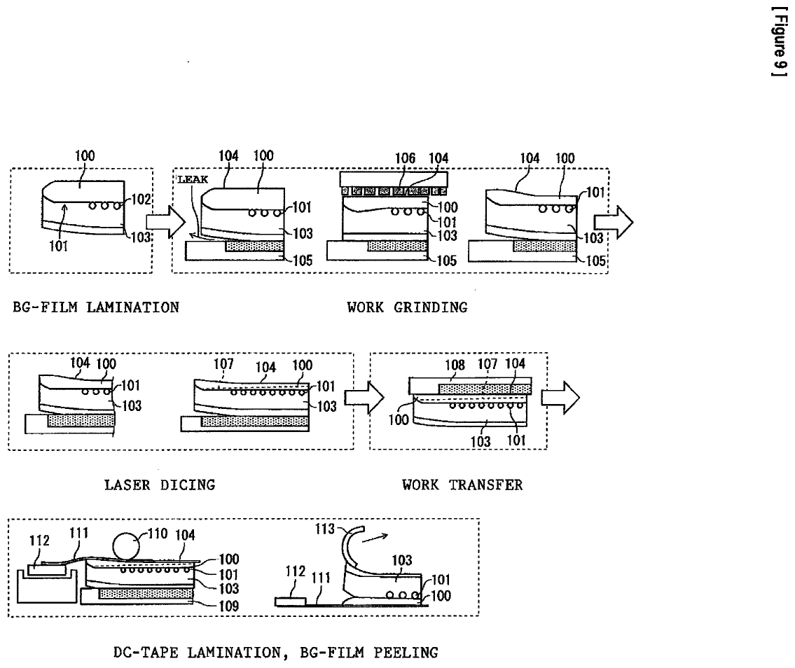

### DESCRIPTION OF EMBODIMENTS

In the following, one embodiment of the present invention is described based on the drawings. Note that, in the following description, when the number of components, numerical values, quantity, range, and so forth are referred to, they are not limited to specific numbers unless explicitly specified and clearly limited to the specific numbers as a principle, and may be larger or smaller than the specific numbers.

Also, when the shape and the positional relation of the components and so forth are referred to, they includes those that are substantially approximate or similar to those shapes and so forth unless explicitly specified and clearly thought not to be as such.

Also, for the purpose of ease of understanding characteristics, the drawings may exaggerate characteristic portions by enlargement or the like, and the dimensional ratio and so forth of the components may not be necessarily the same as the actual ones. Furthermore, in a sectional view, for the purpose of ease of understanding the sectional structure of components, hatching of part of components may be omitted.

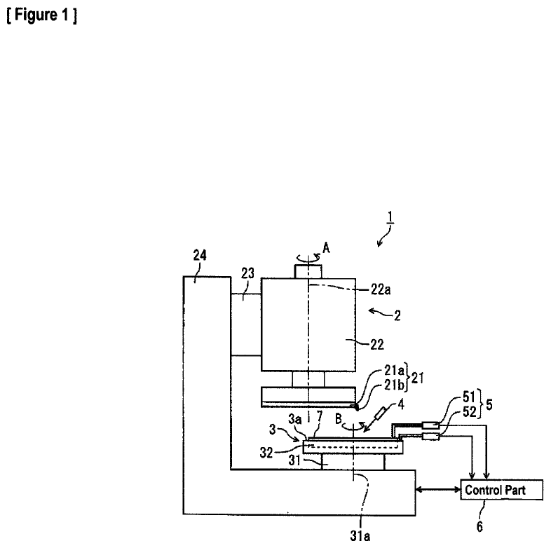

To a fly-cut apparatus 1 depicted in FIG. 1, a silicon-made work 7, which will be described further below, is supplied. The fly-cut apparatus 1 includes cutting means 2 and a chuck 3.

The cutting means 2 includes a fly-cut tool 21, a tool spindle 22, and a spindle feed mechanism 23.

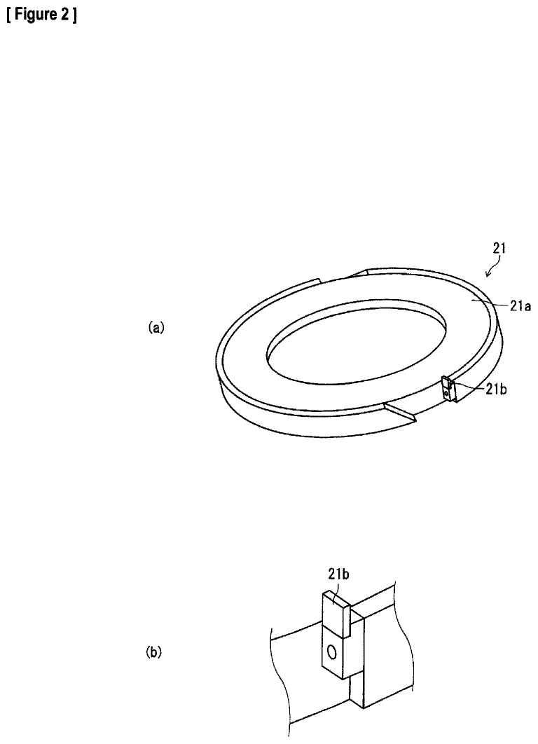

As depicted in FIG. 2 (a) and FIG. 2 (b), the fly-cut tool 21 includes a ring frame 21a to be attached to a lower end of the tool spindle 22 and a cutting tool 21b attached to the outer perimeter of the ring frame 21a. The ring frame 21a is attached to the tool spindle 22 via, for example, a bolt or the like. Also, since the cutting tool 21b is inserted into the ring frame 21a via a bolt 21c, when the cutting tool 21b wears, exchanging only the cutting tool 21b is possible. The cutting tool 21b is, for example, a single stone of diamond.

The tool spindle 22 is configured to be rotationally driven about a rotation axis 22a to an arrow A direction in FIG. 1. To rotationally drive the tool spindle 22, an induction motor is used. Note that the rotating direction of the tool spindle 22 is not limited to the orientation of the arrow A in FIG. 1 and may be reversely oriented.

The spindle feed mechanism 23 causes the tool spindle 22 to ascend and descent in up-down direction. The spindle feed mechanism 23 is configured of, for example, a plurality of linear guides which guide the moving direction of the tool spindle 22 and a ball screw slider mechanism which causes the tool spindle 22 to ascend and descend. The spindle feed mechanism 23 is interposed between the tool spindle 22 and a column 24.

The chuck 3 includes a chuck spindle 31. The chuck spindle 31 is configured to be rotationally driven about a rotation axis 31a to an arrow B direction in FIG. 1. Note that the rotating direction of the chuck spindle 31 is not limited to the orientation of the arrow B in FIG. 1 and may be reversely oriented.

On the upper surface of the chuck 3, an absorbent body 32 made of a porous material such as alumina is buried. Pores of the absorbent body 32 has roughness of, for example, #400, #800, or the like. The chuck 3 includes a conduit, not depicted, which extends through the inside to the front surface. The conduit is connected via a rotary joint not depicted to a vacuum source, a compressed air source, or a water supply source. When the vacuum source starts, the work 7 mounted on the absorbent body 32 is absorbed and retained onto a retaining surface 3a of the chuck 3. Also, when the compressed air source or water supply source starts, absorption between the work 7 and the retaining surface 3a is released.

The fly-cut apparatus 1 includes a cooling water nozzle 4. The cooling water nozzle 4 supplies cooling water such as pure water to a fly-cut line L along which the cutting tool 21b cuts a BG film 75, which will be described below.

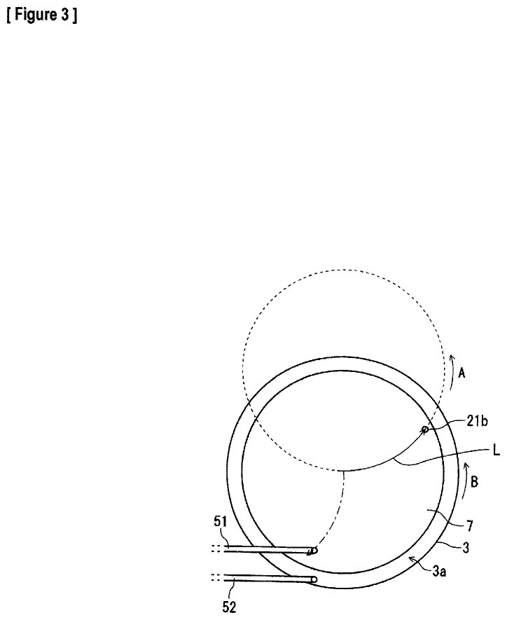

The fly-cut apparatus 1 includes a thickness sensor 5. The thickness sensor 5 is an in-process gauge which measures the thickness of the work 7. Specifically, as depicted in FIG. 3, one measuring head 51 measures the height of the work 7, the other measuring head 52 measures the height of the chuck 3 and, from a difference therebetween, the work 7 can be measured with respect to the chuck 3 during processing.

The operation of the fly-cut apparatus 1 is controlled by a control part 6. The control part 6 controls each components configuring the fly-cut apparatus 1. The control part 6 is configured of, for example, a CPU, a memory, and so forth. Note that the function of the control part 6 may be achieved by controlling using software, or may be achieved by operating using hardware.

Also, the control part 6 functions as a cutting-time predicting part which calculates time when the BG film 75 reaches a finished thickness, based on the number of revolutions of the tool spindle 22, the number of revolutions of the chuck spindle 31, and fall velocity of the spindle feed mechanism 23.

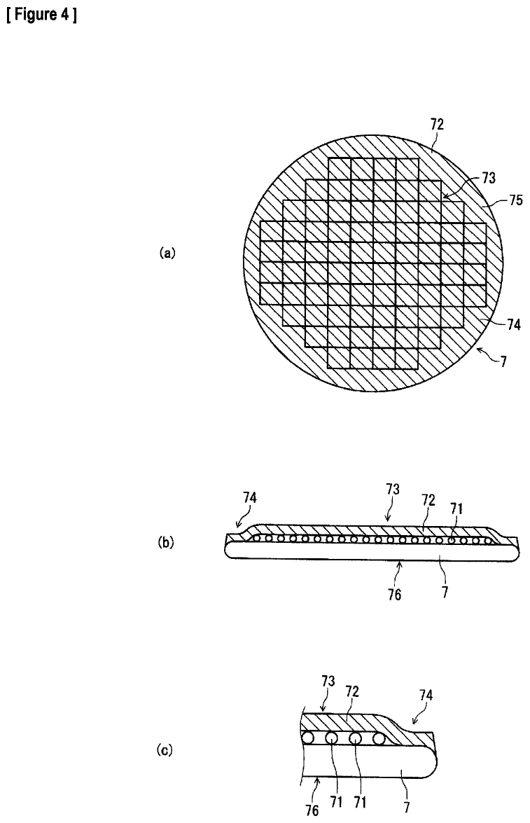

As depicted in FIG. 4 (a) and FIG. 4 (b), the work 7 has a plurality of chips not depicted including the bumps formed on the front surface 72. Specifically, in the work 7, the plurality of chips are formed only in a center region 73 on the front surface 72 of the work 7, and each chip has bumps 71 as electrical contacts. That is, the chips and the bumps 71 are not formed in an outer peripheral region 74 of the work 7. In the following, the center region 73 is referred to as a bump region 73. The bumps 71 have a height of, for example, being equal to or smaller than 100 μm.

On a front surface 72 side of the work 7, the BG film 75 is laminated to cover the entire surface. The BG film 75 protects the chips and the bumps 71 at the time of cutting and at the time of griding a back surface 76, which will be described further below. As depicted in FIG. 4 (b) and FIG. 4 (c), the BG film 75 has the bump region 73 relatively higher than the outer peripheral region 74 in accordance with the height of the bumps 71.

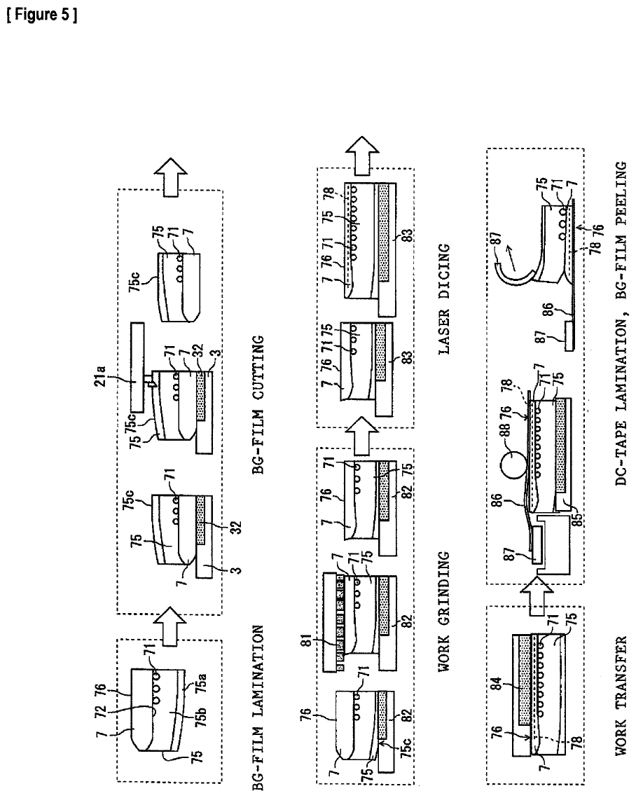

Next, a series of procedure for processing the work 7 is described based on FIG. 5.

### BG-Film Lamination

First, by using a known film laminating apparatus, the BG film 75 is laminated to the front surface 72 of the work 7. The BG film 75 is formed of a base material 75a and an adhesive 75b and, for example, the base material 75a is made of polyolefin and the adhesive 75b is made of acrylic.

### BG-Film Cutting

Next, by using the fly-cut apparatus 1, an upper surface 75c of the BG film 75 is Specifically, first, the back surface 76 of the work 7 is absorbed and retained by cut. the chuck 3. Next, in a state in which the tool spindle 22 and the chuck spindle 31 are each rotated, as cooling water is supplied from the cooling water nozzle 4, the spindle feed mechanism 23 causes the cutting tool 21b to cut into the BG film 75.

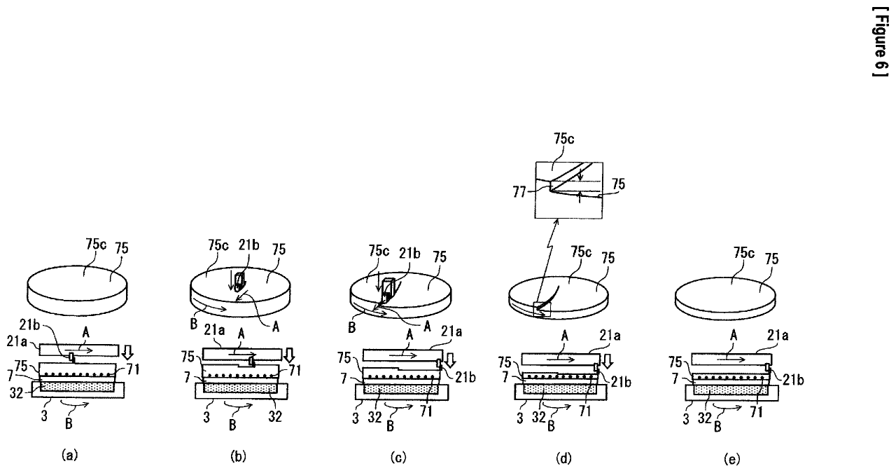

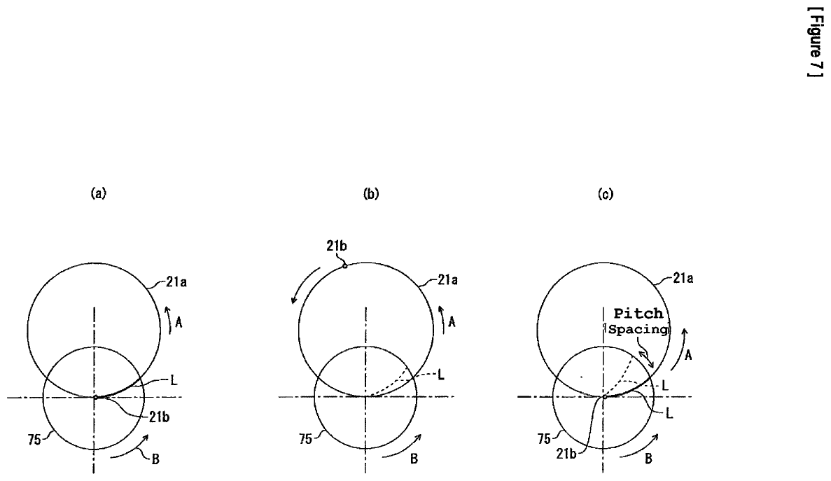

As depicted in FIG. 6 (a) to FIG. 6 (c) and FIG. 7 (a), the cutting tool 21b the upper surface of the BG film 75 is cut from the center toward the outer perimeter. When the cutting tool 21b cuts the BG film 75 from the outer perimeter toward the center, the peripheral edge of the BG film 75 in contact with the cutting tool 21 is elastically deformed, thereby possibly making it impossible to cut into a desired shape. By contrast, with the cutting tool 21b cutting the BG film 75 from the center toward the outer perimeter, the BG film 75 can be stably cut. Various cutting conditions include, for example, the rotational amount of the tool spindle 22 is 3000 rpm, the rotational amount of the chuck spindle 31 is 1 rpm, and the fall velocity of the spindle feed mechanism 23 is 0.2 μm/s.

Also, as for the amount of removal of the BG film 75 to be removed by cutting by the cutting tool 21b once (size of the fly-cut line L), the thickness (depth) is 12 μm in the case of the above-described cutting conditions. Furthermore, as depicted in FIG. 7(a) to FIG. 7(c), the rotational amount of the BG film 75 in one rotation of the cutting tool 21b after the cutting tool 21b cuts the BG film 75 (0.3 mm) corresponds to a pitch spacing between adjacent fly-cut lines.

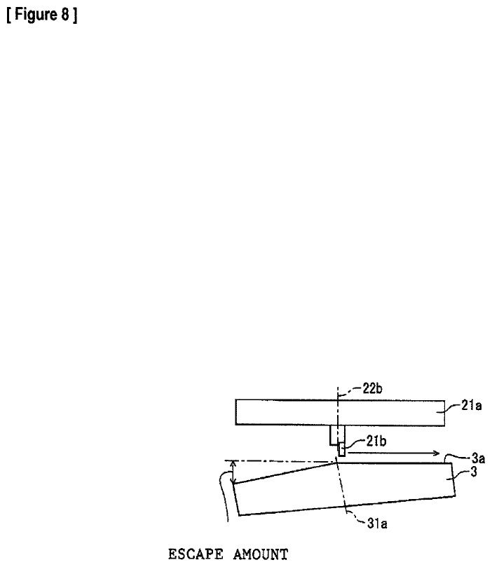

Also, as depicted in FIG. 8, in the chuck 3, the rotation axis 31a is tilted with respect to the rotation axis 22a of the tool spindle 22, and the retaining surface 3a of the chuck 3 is formed in a center-protruding shape, in which its center is higher compared with its outer perimeter. That is, while the chuck 3 and the tool spindle 22 are substantially parallel to each other in a range in which the cutting tool 21b cuts the BG film 75, the chuck 3 is away from the tool spindle 22 on an opposite side of a range in which the cutting tool 21b cuts the BG film 75 across the rotation center of the chuck 3. With this, until the cutting tool 21b returns to the center of the BG film 75 after cutting the BG film 75 from the outer perimeter to the outside, a gap is kept between the BG film 75 and the cutting tool 21b, thereby reducing contacts of the cutting tool 21 with the BG film 75 at an unintended position. Note that in FIG. 7, an escape amount is set at 60 μm, which is a distance from the lower end of the retaining surface 2a to the rotation center of the chuck 3.

Timing of the end of cutting the BG film 75 is determined by the following procedure. That is, the thickness sensor 5 measures the thickness of the work 7 with respect to the chuck 3 during processing. The control part 6 calculates time until the measurement value of the thickness sensor 5 reaches the preset finished thickness of the work 7, based on the number of revolutions of the tool spindle 22, the number of revolutions of the chuck spindle 31, and fall velocity of the spindle feed mechanism 23. When that time elapses, the control part 6 determines that the thickness of the work 7 being processed has reached the finished thickness, and causes feeding by the spindle feed mechanism 23 to stop, as depicted in FIG. 6 (d).

Note that, as depicted in FIG. 3, since the thickness sensor 5 measures the height of the work 7 at a location different from the immediately-previous fly-cut line L, it is required to consider a positional relation between the measurement position of the thickness sensor 5 and the immediately-previous fly-cut line L. For example, the thickness of the work 7 at the measurement position of the thickness sensor 5 of FIG. 3 is thicker than the thickness of the work 7 on the immediately-previous fly-cut line L, approximately 12 μm may be subtracted from the measured value of the thickness sensor 5 to make the measurement value of the thickness sensor 5 substantially match the thickness of the work 7 on the immediately-previous fly-cut line L. Note that any change can be made to the shape of the BG film 75 after fly-cut (that is, total amount of removal by fly-cut) in accordance with the height of the bumps 71.

When the work 7 reaches the finished thickness, the upper surface 75c of the BG film 75 is a spiral curved surface and, furthermore, as depicted in FIG. 6 (d), a step difference 77 is formed on the immediately-previous fly-cut line L. Thus, as depicted in FIG. 6 (e), spark-out is performed, in which the tool spindle 22 and the chuck spindle 31 are each rotated in a state in which the spindle feed mechanism 23 is at a standstill, thereby allowing the upper surface 75c of the BG film 75 to be finished as being smooth.

In this manner, of the upper surface 75c of the BG film 75, the center region 73 formed relatively thickly with respect to the outer peripheral region 74 is removed by the cutting tool 21b, thereby allowing the thickness of the work 7 including the BG film 75 to be formed substantially uniformly over the entire surface.

### Work Grinding

Next, the work 7 is transferred to a known grinding apparatus, and the back surface of the work 7 is ground by a grindstone 81. Here, with the upper surface 75c of the BG film 75 being fly-cut, irrespective of the bumps 71, the entire upper surface 75c of the BG film 75 is substantially flatly absorbed and retained by a grinding chuck 82. Thus, vacuum leakage at the outer perimeter of the work 7 and flapping of the work 7 at the time of grinding are reduced, and the back surface 76 of the work 7 after grinding is substantially flatly formed.

### Laser Dicing

Next, the work 7 is transferred to a known laser dicing apparatus, and laser dicing (ML) is performed, in which laser light with a wavelength passing through the work 7 is gathered to the inside of the work 7 to form a modification line 78 in a lattice in a planar view. The modification line 78 serves as a starting point for dividing the work 7 when the work 7 is cut into pieces. With the upper surface 75c of the BG film 75 being fly-cut, irrespective of the bumps 71, the BG film 75 is substantially flatly absorbed and retained by a ML chuck 83. Also, with the back surface 76 of the work 7 being substantially flatly ground, the modification line 78 can be stably formed at a predetermined depth from the back surface 76 of the work 7.

### Work Transfer

Next, the back surface 76 of the work 7 is absorbed and retained by a chuck 84 of a known transfer arm, and the work 7 is transferred to a dicing (DC) tape lamination apparatus. Here, since the modification line 78 is uniformly formed at the predetermined depth from the back surface 76 of the work 7, even if the work 7 is suctioned with negative pressure, it is possible to safely transfer the work 7 without causing a crack in the work 7.

### DC-Tape Lamination, BG-Film Peeling

Next, by using the known DC tape lamination apparatus, the work 7 translocated to the chuck 85 is laminated via a DC tape 86 to a dicing frame 87. Lamination of the DC tape 86 is performed by a rolling roller 88 pressing the DC tape 86 onto the back surface 76. Here, since the modification line 78 is uniformed formed at the predetermined depth from the back surface 76 of the work 7, even if the rolling roller 88 pressurizes the work 7, it is possible to safely laminate the DC tape 86 without causing a crack in the work 7.

Thereafter, by using a known peeling apparatus, the BG film 75 is peeled from the work 7. In peeling of the BG film 75, by rolling up a peeling tape 89 press-fitted to the BG film 75, the BG film 75 is peeled from the front surface 72 of the work 7. Here, since the modification line 78 is uniformly formed at the predetermined depth from the back surface 76 of the work 7, also when the BG film 75 is peeled from the work 7, it is possible to safely laminate the DC tape 86 without causing a crack in the work 7.

As described above, the fly-cut apparatus 1 according to the embodiment of the present invention is the fly-cut apparatus 1 which cuts the upper surface 75c of the BG film 75 laminated to the work 7 including the bump region 73 with the bumps 71 formed on the front surface 72 and the outer peripheral region 74 around the bump region 73, the apparatus is configured to include a fly-cut tool 21, a tool spindle 22 with a lower end to which the fly-cut tool 21 is attached, and capable of ascending and descending in a state of rotating the fly-cut tool 21, and a chuck 3 which rotatably retains the work 7, and the fly-cut tool 21 cuts the upper surface 75 of the BG film 75 from a center toward an outer perimeter.

According to this structure, with the center region 73 being cut to be relatively thinner than the outer peripheral region 74 of the BG film 75, when the upper surface 75c side of the BG film 75 is absorbed and retained by the chuck 3, the entire surface of the BG film 75 can be absorbed and retained by the chuck 3. Thus, the work 7 can be safely ground. Also in the ML process, the modification line 78 is formed at a substantially constant depth from the back surface 76 of the work 7. Thus, the occurrence of a microcrack in the work 7 can be reduced when the work 7 is transferred, the DC tape 86 is laminated, or when the BG film 75 is peeled.

Also, the fly-cut apparatus 1 is configured in which the fly-cut tool 21 includes the ring frame 21a to be attached to the tool spindle 22 and the cutting tool 21b to be inserted to the outer perimeter of the ring frame 21a and capable of cutting the BG film 75.

According to this structure, the cutting tool 21b can be inserted via the ring frame 21a to the tool spindle 22.

Furthermore, the fly-cut apparatus 1 is configured in which the chuck 3 has the rotation axis 31a set as being tilted by a predetermined angle, and the chuck 3 has the retaining surface 3a which retains the work 7, the retaining surface 3a formed in a center-protruding shape, in which its center is higher compared with its outer perimeter.

According to this structure, until the cutting tool 21b returns to the center of the BG film 75 after cutting the BG film 75 from the outer perimeter to the outside, a gap is kept between the BG film 75 and the cutting tool 21b, thereby reducing contacts of the cutting tool 21 with the BG film 75 at an unintended position.

Still further, the fly-cut apparatus 1 is configured to include the cooling water nozzle 4 which supplies cooling water to the upper surface 75c of the BG film 75.

According to this structure, when the BG film 75 is cut, it is possible to reduce excessive increase in temperature of the BG film 75.

Still further, the fly-cut apparatus 1 is configured to include the thickness sensor 5 which measures a thickness of the BG film 75 during cutting by the fly-cut tool 21 and the control part 6 which calculates time when the BG film 75 reaches a finished thickness, based on a measurement thickness of the thickness sensor 5, the number of revolutions of the fly-cut tool 21, the number of revolutions of the chuck 3, and fall velocity of the tool spindle 22.

According to this structure, the finished thickness of the BG film 75 can be appropriately managed.

Yet still further, other than the above, the present invention can be variously modified as long as such modifications do not deviate the spirit of the present invention, and it goes without saying that the present invention covers the modified ones.

### REFERENCE SIGNS LIST

1: fly-cut apparatus
2: cutting means
21: fly-cut tool
21a: ring frame
21b: cutting tool
21c: bolt
22: tool spindle
22a crotation axis
23: spindle feed mechanism
24: column
3: chuck
3a retaining surface
31: chuck spindle
31a: rotation axis
32: absorbing body
4: cooling water nozzle
5: thickness sensor
51, 52: measuring head
6: control part
7: work
71: bump
72: front surface
73: bump region
74: outer peripheral region
75: BG film
75a: base material
75b: adhesive
75c: upper surface
76: back surface
77: step difference
78: modification line
L: fly-cut line

1. A fly-cut apparatus which cuts an upper surface of a protective film laminated to a work including a bump region with bumps formed on a front surface and an outer peripheral region around the bump region, the apparatus comprising:
a fly-cut tool;
a tool spindle with a lower end to which the fly-cut tool is attached, and capable of ascending and descending in a state of rotating the fly-cut tool; and
a chuck which rotatably retains the work, wherein
the fly-cut tool cuts the upper surface of the protective film from a center toward an outer perimeter.

2. The fly-cut apparatus according to claim 1, wherein the fly-cut tool includes
a ring frame to be attached to the tool spindle, and
a cutting tool to be inserted to an outer perimeter of the ring frame and capable of cutting the protective film.

3. The fly-cut apparatus according to claim 1, wherein
the chuck has a rotation axis set as being tilted by a predetermined angle, and
the chuck has a retaining surface which retains the work, the retaining surface formed in a center-protruding shape, in which a center is higher compared with an outer perimeter.

4. The fly-cut apparatus according to any one of claim 1, further comprising a cooling water nozzle which supplies cooling water to the upper surface of the protective film.

5. The fly-cut apparatus according to any one of claims 1, further comprising:
a thickness sensor which measures a thickness of the protective film during cutting by the fly-cut tool; and
a cutting-time predicting part which calculates time when the protective film reaches a finished thickness, based on a measurement value of the thickness sensor, number of revolutions of the fly-cut tool, number of revolutions of the chuck, and fall velocity of the tool spindle.
